(19) United States
(12) Patent Application Publication
(10) Pub. No.: US 2026/0005212 A1
(43) Pub. Date: Jan. 1, 2026

(54) CBA SEMICONDUCTOR DEVICE WITH EDGE CONNECTIONS

(71) Applicant: Sandisk Technologies, Inc., Milpitas, CA (US)

(72) Inventors: Izzie Zhang, Shanghai (CN); Cong Zhang, Shanghai (CN); Elley Zhang, Shanghai (CN); Derek Mong, Penang (MY); Shrikar Bhagath, San Jose, CA (US); Fen Yu, Shanghai (CN)

(73) Assignee: Sandisk Technologies, Inc., Milpitas, CA (US)

(21) Appl. No.: 18/758,785

(22) Filed: Jun. 28, 2024

(51) Int. Cl. H01L 25/18; H01L 21/66; H01L 23/00; H10B 80/00

(52) U.S. Cl. CPC H01L 25/18; H01L 22/32; H01L 24/08; H10B 80/00; H01L 24/13; H01L 2224/08145; H01L 2224/13023; H01L 2225/06551; H01L 2225/06596; H01L 2924/1431; H01L 2924/1438

(57) ABSTRACT

A semiconductor device is disclosed including an integrated memory module. The integrated memory module may include a pair of semiconductor die, which together, operate as a single, integrated flash memory. In one example, the first die may include the memory cell array and the second die may include the logic circuit such as CMOS integrated circuits. In one example, the second die may be flip-chip bonded to the first die. The flip-chip bond pads on the first and second dies may be made small, with a small pitch, to allow a large number of electrical interconnections between the first and second semiconductor dies.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

Recently, ultra high density memory devices have been proposed using a 3D stacked memory structure having strings of memory cells formed into layers. One such storage device is sometimes referred to as a Bit Cost Scalable (BiCS) architecture. These memory cells are bonded to a logic circuit for controlling read/write to the memory cells. The logic circuit wafer, often fabricated using complementary metal-oxide-semiconductor (CMOS) technology, may be bonded to the memory structure wafer to form a so-called CMOS bonded array (CBA) wafer array.

As the number of memory layers in 3D memory structures increases to meet ever growing memory demands, it is becoming harder to find space on a surface of the dies on the CBA wafer array for the needed electrical connections.

### DESCRIPTION OF THE DRAWINGS

FIG. 1 is a flowchart for forming a semiconductor device according to embodiments of the present technology.

FIG. 2 is a top view of a first semiconductor wafer, and a first semiconductor die therefrom, according to embodiments of the present technology.

FIG. 3 is a top view of a second semiconductor wafer, and a second semiconductor die therefrom, according to embodiments of the present technology.

FIG. 4 is a front cross-sectional edge view of a first semiconductor die according to embodiments of the present technology.

FIG. 5 is an end cross-sectional view of a first semiconductor die according to embodiments of the present technology.

FIG. 6 is a front cross-sectional edge view of a second semiconductor die according to embodiments of the present technology.

FIG. 7 is an end cross-sectional view of a second semiconductor die according to embodiments of the present technology.

FIG. 8 is a front cross-sectional edge view of an CBA memory module including a first semiconductor die bonded to a second semiconductor die according to embodiments of the present technology.

FIG. 9 is a perspective view of a CBA memory module including a first semiconductor die bonded to a second semiconductor die according to embodiments of the present technology.

FIG. 10 is a perspective view of a CBA memory module including a first semiconductor die bonded to a second semiconductor die according to alternative embodiments of the present technology.

FIG. 11 is a CBA semiconductor device including a plurality of stacked CBA memory modules at a first stage in assembly according to embodiments of the present technology.

FIG. 12 is a CBA semiconductor device including a plurality of stacked CBA memory modules at a second stage in assembly according to embodiments of the present technology.

FIG. 13 is a CBA semiconductor device including a plurality of stacked CBA memory modules at a third stage in assembly according to embodiments of the present technology.

FIGS. 14-17 are perspective views of a CBA semiconductor device including a substrate with foldable sides according to alternative embodiments of the present technology.

### DETAILED DESCRIPTION

The present technology will now be described with reference to the figures, which in embodiments, relate to a semiconductor device including a plurality of CBA memory modules. Each CBA memory module may include a pair of semiconductor dies, which together, operate as a single, integrated flash memory. The first die may comprise a memory array and the second die may comprise a CMOS logic circuit. The dies may be bonded to each other at the wafer level, for example by Cu—Cu bonding or hybrid bonding. Each CBA memory module may comprise a number of bond pads including test pads and signal-carrying input/output (I/O) bond pads. In accordance with aspects of the present technology, at least some of these pads may be moved or extended to a vertical edge of the CBA memory module so that such edge pads are exposed at a vertical edge when the CBA memory module is diced. In embodiments, just the I/O bond pads may be exposed at the vertical edge of the CBA memory module. In further embodiments, both the I/O bond pads and the test pads may be exposed at the vertical edge of the CBA memory module.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

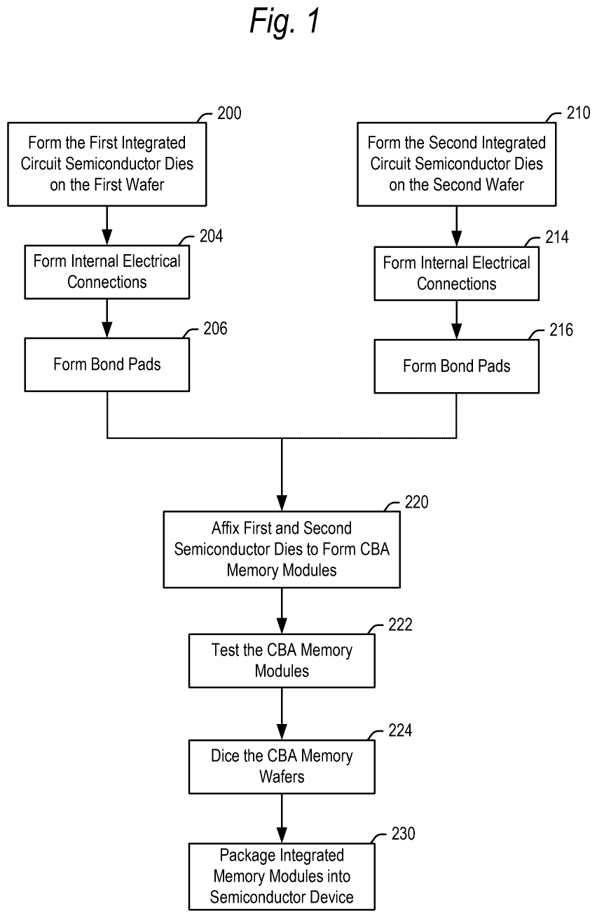

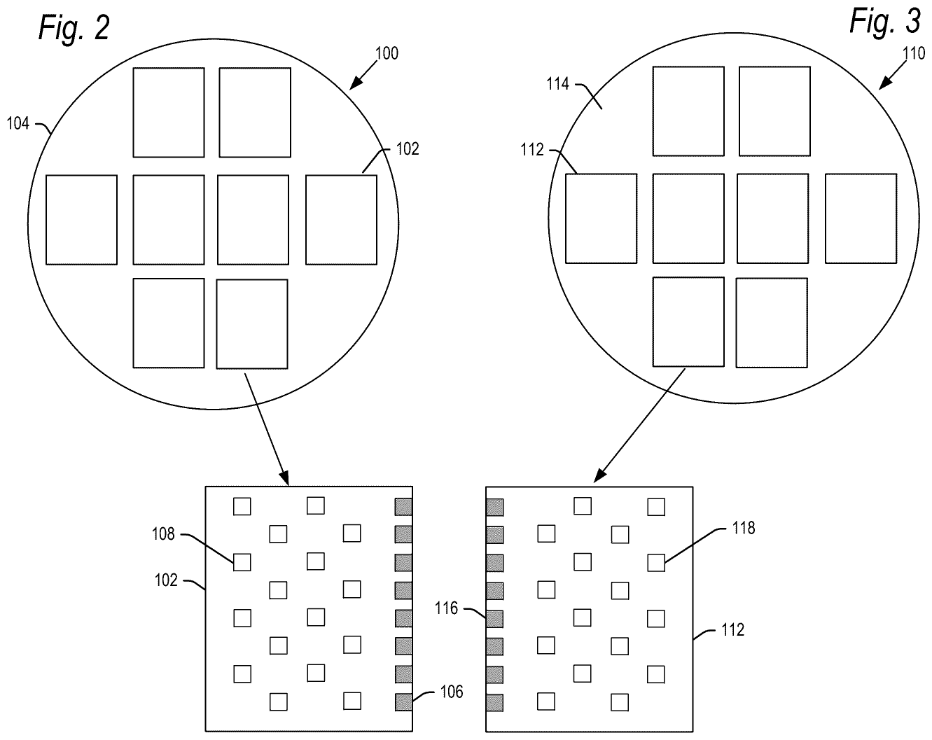

An embodiment of the present technology will now be explained with reference to the flowchart of FIG. 1, and the views of FIGS. 2-17. In step 200, a first semiconductor wafer 100 may be processed into a number of first semiconductor dies 102 as shown in FIG. 2. The first semiconductor wafer 100 may start as an ingot of wafer material which may be monocrystalline silicon grown according to either a Czochralski (CZ) or floating zone (FZ) process. However, first wafer 100 may be formed of other materials and by other processes in further embodiments.

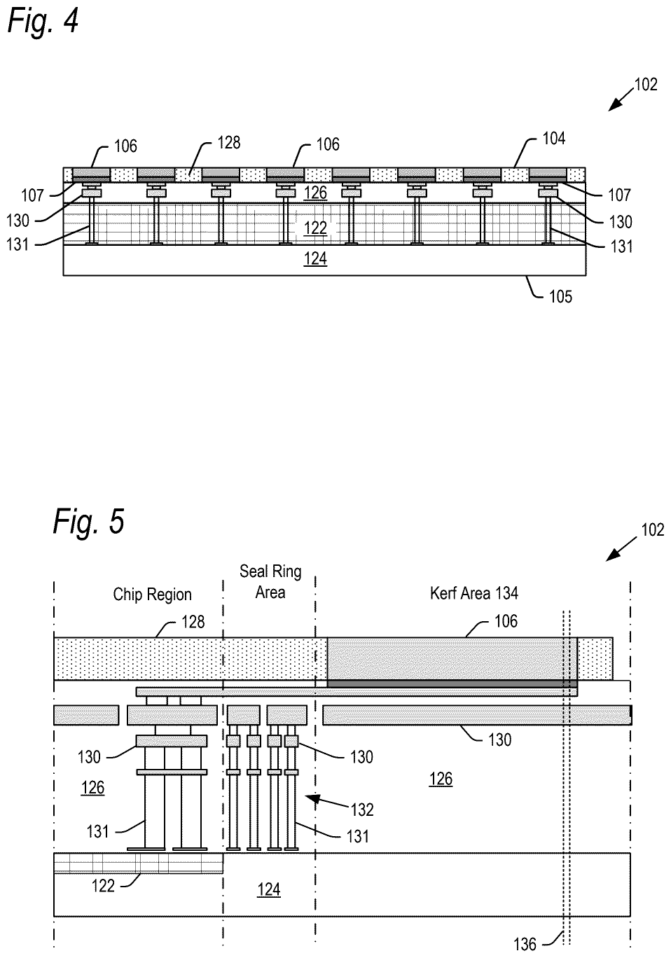

The semiconductor wafer 100 may be cut from the ingot and polished on both the first major planar surface 104, and second major planar surface 105 (FIG. 4) opposite surface 104, to provide smooth surfaces. The first major surface 104 may undergo various processing steps to divide the wafer 100 into the respective first semiconductor dies 102, and to form integrated circuits of the respective first semiconductor dies 102 on and/or in the first major surface 104.

In particular, in step 200, the first semiconductor die 102 may be processed in embodiments to include integrated circuit memory cell array 122 formed in a dielectric substrate including layers 124 and 126 as shown in the cross-sectional front view of FIG. 4. In embodiments, the memory cell array 122 may be formed as a 3D stacked memory structure having strings of memory cells formed into layers. However, it is understood that the first semiconductor die 102 may be processed to include integrated circuits other than a 3D stacked memory structure. A passivation layer 128 may be formed on top of the upper dielectric film layer 126.

After formation of the memory cell array 122, internal electrical connections may be formed within the first semiconductor die 102 in step 204. The internal electrical connections may include multiple layers of metal interconnects 130 and vias 131 formed sequentially through layers of the dielectric film 126. As is known in the art, the metal interconnects 130, vias 131 and dielectric film layers 126 may be formed a layer at a time using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 130 may be formed of a variety of electrically conductive metals including for example copper and copper alloys as is known in the art, and the vias 131 may be lined and/or filled with a variety of electrically conductive metals including for example tungsten, copper and copper alloys as is known in the art.

In step 206, bond pads may be formed on the major planar surface 104 of the first semiconductor dies 102. As shown in FIGS. 2 and 4, these bond pads may include a first group of bond pads 106, referred to herein as I/O bond pads 106, which may be used to carry signals to and from the finished semiconductor dies 102 as explained below. The bond pads may further include a second group of bond pads 108, referred to herein as test pads 108, used to test the operation of the semiconductor dies 102 as explained below. In accordance with one embodiment of the present technology, the first group of I/O bond pads 106 may be formed at an edge of the semiconductor die 102 so as to be exposed at a vertical edge of the semiconductor die 102 as explained below. In a further embodiment both the first group of I/O bond pad 106 and the second group of bond pads 108 may be formed at an edge of the semiconductor die 102 so as to be exposed at a vertical edge of the semiconductor die 102 as explained below.

The passivation layer 128 may be etched, and each bond pad 106, 108 may be formed over a liner 107 in the etched regions of the passivation layer. As is known in the art, the bond pads 106, 108 may be formed for example of copper, aluminum and alloys thereof, and the liner 107 may be formed for example of a titanium/titanium nitride stack such as for example Ti/TiN/Ti, though these materials may vary in further embodiments. The bond pads 106, 108 and liner 107 may be applied by vapor deposition and/or plating techniques. The integrated circuits 122 may be electrically connected to the bond pads 106 and/or 108 by the metal interconnects 130 and vias 131.

FIG. 2 shows semiconductor dies 102 on wafer 100, and bond pads 106, 108 in a given pattern on one of the semiconductor dies 102. The number of first semiconductor dies 102 shown on wafer 100 in FIG. 2 is for illustrative purposes, and wafer 100 may include more first semiconductor dies 102 than are shown in further embodiments. Similarly, the pattern of bond pads 106, 108, as well as the number of bond pads 106, 108, on the first semiconductor die 102 are shown for illustrative purposes. Each first die 102 may include more bond pads 106 and/or 108 than are shown in further embodiments, and may include various other patterns of bond pads 106, 108. However, as noted, at least one group of bond pads 106, 108 are positioned at an edge of the semiconductor dies 102.

FIG. 5 is a cross-sectional edge view, orthogonal to the cross-sectional front view of FIG. 4, that shows how the first group of bond pads 106 are formed at the edge of each semiconductor die 102 in this embodiment. FIG. 5 shows different vertical regions of the semiconductor die 102, including a chip region within which the memory array 122 is formed, a seal ring area within which a seal ring 132 is formed and a kerf area 134 within which the bond pads 106 are formed. The seal ring 132 is formed of a series of metallization layers 130 and vias 131, and serves as a boundary at the edge of the semiconductor die 102. Its primary purpose is to provide structural support and protection to the memory array 122 and active circuitry within the die 102. The chip regions and seal ring areas may together be referred to herein as the active area of a semiconductor die 102.

FIG. 5 also shows dicing line 136 representing a line along which the semiconductor dies 102 are cut from wafer 100 as explained below. As shown, the dicing line 136 cuts through the die bond pads 106 to leave an edge of the die bond pads 106 exposed at the edge of each semiconductor die 102 upon dicing from wafer 100. This exposed edge of the die bond pads 106 may be referred to herein as vertical bond pad face 106a. In one embodiment, the die bond pads 106 may be severed 1 μm to 5 μm from a proximal edge of the die bond pads, though the cut may be made closer or farther from the proximal edge of the die in further embodiments.

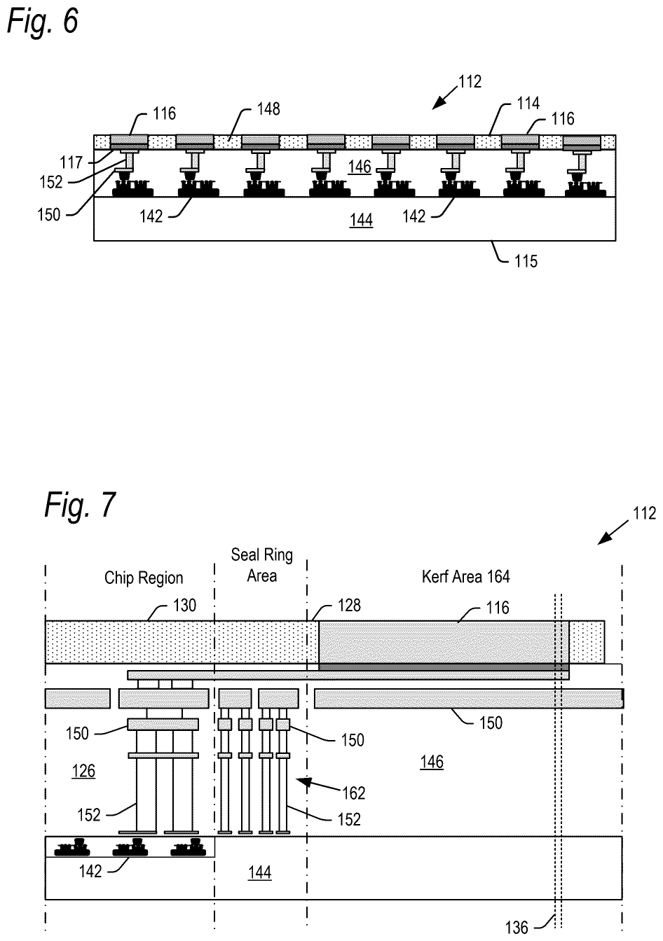

Before, after or in parallel with the formation of the first semiconductor dies on wafer 100, a second semiconductor wafer 110 may be processed into a number of second semiconductor dies 112 in step 210 as shown in FIG. 3. The semiconductor wafer 110 may start as an ingot of monocrystalline silicon grown according to either a CZ, FZ or other process. The second semiconductor wafer 110 may be cut and polished on both the first major surface 114, and second major surface 115 (FIG. 6) opposite surface 114, to provide smooth surfaces. The first major surface 114 may undergo various processing steps to divide the second wafer 110 into the respective second semiconductor dies 112, and to form integrated circuits of the respective second semiconductor dies 112 on and/or in the first major surface 114.

In one embodiment, the second semiconductor dies 112 may be processed to include integrated circuits 142 formed in a dielectric substrate including layers 144 and 146 as shown in the cross-sectional edge view of FIG. 6. Integrated circuits 142 may be configured as logic circuits to control read/write operations for one or more integrated memory cell arrays. The logic circuits may be fabricated using CMOS technology, though the logic circuits may be fabricated using other technologies in further embodiments. The second semiconductor dies 112 may include other and/or additional integrated circuits in further embodiments as explained below. A passivation layer 148 may be formed on top of the upper dielectric film layer 146.

After formation of the integrated circuits 142, internal electrical connections may be formed within the second semiconductor die 112 in step 214. The internal electrical connections may include multiple layers of metal interconnects 150 and vias 152 formed sequentially through layers of the dielectric film 146. The metal interconnects 150 and vias 152 may be formed of the same materials and in similar processes to interconnects 130 and vias 131 described above (though in different patterns).

In step 216, bond pads may be formed on the major planar surface 114 of the second semiconductor dies 112. As shown in FIGS. 3 and 6, these bond pads may include a first group of bond pads 116, referred to herein as I/O bond pads 116, which may be used to carry signals to and from the finished semiconductor dies 112 as explained below. The bond pads may further include a second group of bond pads 118, referred to herein as test pads 118, used to test the operation of the semiconductor dies 112 as explained below. In accordance with one embodiment of the present technology, the first group of I/O bond pads 116 may be formed at an edge of the semiconductor die 112 so as to be exposed at a vertical edge of the semiconductor die 112 as explained below. In a further embodiment both the first group of I/O bond pad 116 and the second group of bond pads 118 may be formed at an edge of the semiconductor die 112 so as to be exposed at a vertical edge of the semiconductor die 112 as explained below.

FIG. 3 shows the second semiconductor dies 112 on wafer 110, and a given pattern of bond pads 116 and 118 on one of the second semiconductor dies 112. The number of second semiconductor dies 112 shown on wafer 110 in FIG. 3 is for illustrative purposes, and wafer 110 may include more second semiconductor dies 112 than are shown in further embodiments. Similarly, the pattern of bond pads 116 and 118, as well as the number of bond pads 116 and 118, on the second semiconductor die 112 are shown for illustrative purposes. Each second die 112 may include more bond pads 116 and/or 118 than are shown in further embodiments, and may include various other patterns of bond pads 116 and/or 118, with the requirement that the bond pads 116 at the edge match the pattern of bond pads 106 at the edge of the first dies 102.

FIG. 7 is a cross-sectional edge view, orthogonal to the cross-sectional front view of FIG. 6, that shows how the first group of bond pads 116 are formed at the edge of each semiconductor die 112 in this embodiment. FIG. 7 shows different vertical regions of the semiconductor die 112, including a chip region within which the CMOS logic circuits 142 are formed, a seal ring area within which a seal ring 162 is formed and a kerf area 164 within which the bond pads 116 are formed. As above, the seal ring 162 is formed of a series of metallization layers 150 and vias 152, and serves as structural support and protection to the CMOS logic circuits 142 and active circuitry within the die 112. The chip regions and seal ring areas may together be referred to herein as the active area of a semiconductor die 112.

FIG. 5 also shows dicing line 136 representing a line along which the semiconductor dies 112 are cut from wafer 110 as explained below. As shown, the dicing line 136 cuts through the die bond pads 116 to leave an edge of the die bond pads 116 exposed at the edge of each semiconductor die 112 upon dicing from wafer 110. This exposed edge of the die bond pads 116 may be referred to herein as vertical bond pad face 116a. In one embodiment, the die bond pads 116 may be severed 1 μm to 5 μm from a proximal edge of the die bond pads, though the cut may be made closer or farther from the proximal edge of the die 112 in further embodiments.

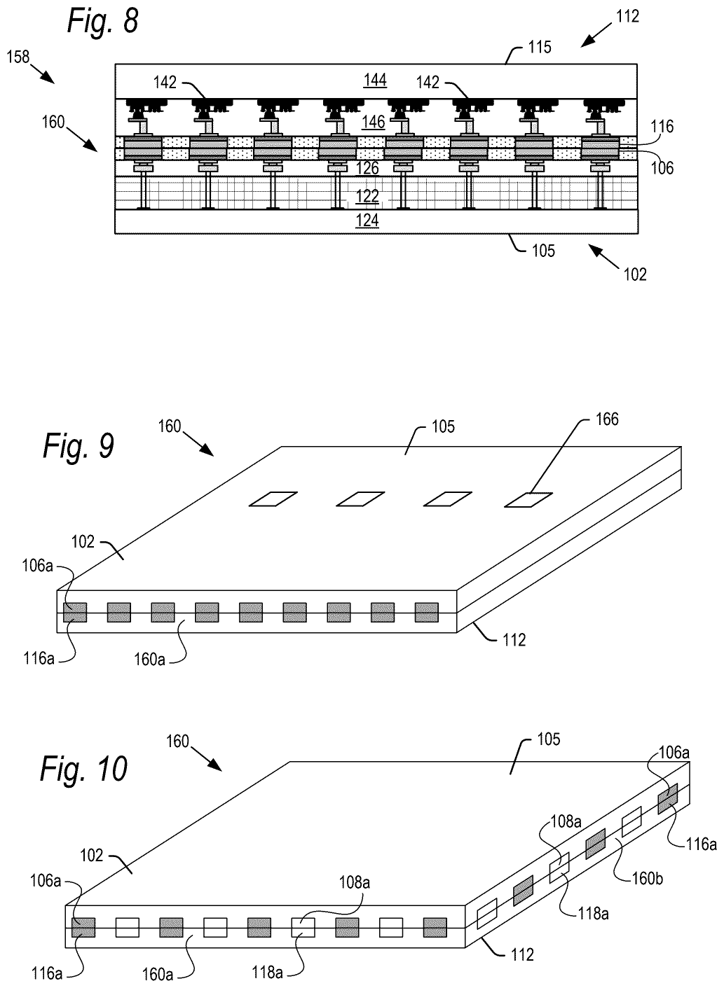

Once the fabrication of first and second semiconductor dies 102 and 112 on wafers 100 and 110 is complete, the first and second semiconductor wafers 100 and 110 may be affixed to each other in step 220. In particular, one of the wafers (e.g., wafer 110) may be flipped over, and the dies 102, 112 on respective wafers 100 and 110 may be affixed to each other by physically and electrically coupling the bond pads 106 on dies 102 to bond pads 116 on dies 112. A cross-sectional front view of bonded dies 102, 112 is shown in FIG. 8. In embodiments, the bond pads 108 on dies 102 may also be physically and electrically coupled to the bond pads 118 on dies 112. The wafers 100 and 110 may be joined by Cu—Cu bonding of the respective bond pads on wafers 100 and 110. Other bonding techniques are possible, including for example hybrid bonding and oxide bonding. The bonded semiconductor wafers 100, 110 may be referred to herein as CBA wafers 158, and the respective bonded dies 102, 112 may be referred to herein as CBA memory modules 160.

Once bonded together, the individual memory modules 160 may be tested in step 222, using probes or other contacts on the surface of the test pads 108/118. These tests may for example include various tests to sort the dies 102 on wafer 100 into known good dies (KGDs) and other lower bin classifications depending on the operational quality of the dies 102.

After testing, the CBA memory wafer 158 may be diced in step 224 to form individual CBA memory modules 160 as shown for example in FIG. 9. Various dicing techniques may be used, including for example sawing with a saw blade along cut lines 136, or so-called stealth laser dicing. In stealth laser dicing, a laser is focused within the surfaces of wafers 100 and 110, around the outlines of each semiconductor die 102, 112 and along cut lines 136, to create voids which result in cracking along vertical crystalline planes to effectively dice the CBA memory modules 160 from the wafer 158. The wafer 158 may be mounted on a dicing tape (not shown), which may be stretched to separate the CBA modules 160 from each other once diced.

FIG. 9 is a perspective view of a CBA module 160 diced from CBA wafer 158. As shown, the vertical bond pad edges 106a of pads 106 from die 102 are exposed at a vertical face 160a of CBA memory module 160. Likewise, the vertical bond pad edges 116a of pads 116 of die 112 are exposed at vertical face 160a. As bond pads 106 and 116 are bonded together, the vertical bond pad edges 106a and 116a align with each other in vertical face 160a.

The above embodiments show no I/O bond pads 106, 116 on an interior of dies 102 and 112. However, in further embodiments, some bond pads 106, 116 may be exposed at one or more vertical faces of the CBA memory module 160 as described above, and some bond pads 106, 116 may be provided at an interior of the CBA module 160 (spaced inward from the vertical faces). In such embodiments, the coupled interior pads 106, 116 may be electrically coupled by through silicon vias (TSVs) (not shown) extending to pads 166 (FIG. 9), for example on the inactive surface 105 of the first die 102. While FIG. 9 shows a single group of such pad 166, it is understood that there may be more or less such bond pads 166, in different positions, in further embodiments.

Provision of the edge pads 106a, 116a provides a number of advantages. For example, exposure of such pads at the vertical faces reduces or eliminates the number of pads (166) that are needed at the major planar surfaces (105) of the CBA memory module. This potentially allows a reduction in the footprint (length and/or width) of the CBA memory module without sacrificing storage capacity or bandwidth. Moreover, for applications requiring high bandwidth, the number of I/O pads may be increased (by using the vertical faces of a CBA memory module 160) without having to increase the footprint of the CBA memory module. Further still, creation of TSVs to the pads 166 on the inactive surface of CBA memory module 160 is expensive. Use of these TSVs may be reduced or eliminated by using the edge pads of the present technology.

As noted above, test pads 108, 118 are used to test dies 102, 112 before they are assembled together into CBA memory modules 160. Once the dies 102, 112 are assembled together into CBA memory modules 160, the test pads 108, 118 are buried within the interior of CBA memory modules 160. However, in a further embodiment, instead of just I/O bond pads 106, 116 being exposed at a vertical edge 160a of CBA memory module 160, the test pads 108, 118 may also be exposed at the vertical edge 160a. As shown in the perspective view of FIG. 10, such an embodiment results in vertical bond pads edges 108a, 118a exposed at vertical face 160a. In this embodiment, the test pads 108 may be fabricated at the edge of dies 102, just as explained above for I/O bond pads 106. Similarly, the test pads 118 may be fabricated at the edge of dies 112, just as explained above for I/O bond pads 116. In this embodiment, the testing steps 208 and 218 for dies 102, 112 may instead be performed after the CBA memory modules 160 are diced from the CBA wafer 158. In addition to (or instead of) I/O bond pads 106, 116 and/or test pads 118, 118, power and ground pads may also be provided at a vertical face of CBA memory module 160 in further embodiments.

In embodiments, the pads 106, 116 (or pads 106, 116, 108 and 118) may be exposed at a single vertical face 160a as shown in FIG. 9. However, the pads 106, 116 and/or pads 108, 118 may be exposed at one vertical face, two adjoining vertical faces, two opposed vertical faces, three vertical faces or all four vertical faces of CBA memory module 160. FIG. 10 shows an embodiment where pads 106, 116, 108, 118 are exposed at a pair of adjoining vertical faces 160a and 160b.

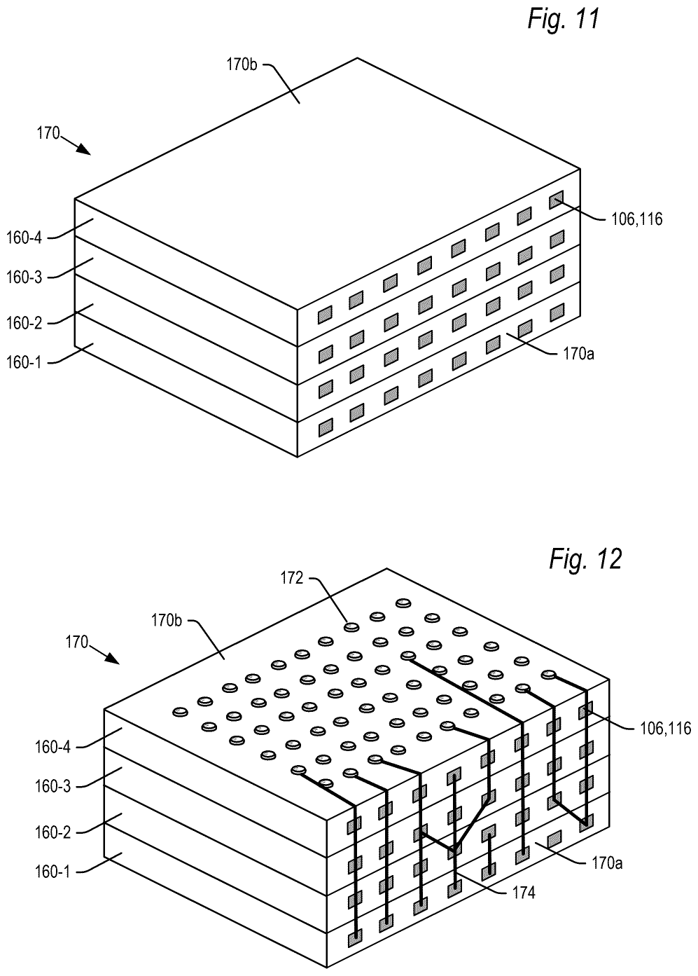

In step 230, a number of the CBA memory modules may be packaged together into a CBA semiconductor device 170, as shown for example in FIG. 11. FIG. 11 shows four CBA memory modules 160 stacked together—160-1, 160-2, 160-3 and 160-4. It understood that the CBA semiconductor device 170 can have other numbers of CBA modules 160, including 1, 2, 3, 8, 16, 32 or more, as well as any number therebetween. A layer of die attach film (DAF) may be formed on a bottom surface of each CBA memory module 160 before then are picked from CBA wafer 158, which DAF layer allows the modules 160 to be stacked. In the embodiment shown, the edge pads 106a, 116a are provided in a vertical sidewall 170a of the CBA semiconductor device 170. Vertical sidewall 170a comprises a planar edge of device 170 formed of aligned vertical faces 160a of each CBA memory module 160.

FIG. 12 shows the CBA semiconductor device 170 processed to further include a number of solder bumps 172 affixed to a surface 170b of CBA semiconductor device 170 and a pattern of electrical traces 174 formed on sidewall 170a to electrically connect the CBA memory modules 160 to each other and the solder bumps 172. The electrical traces 174 are formed over, and lie in contact with, the vertical edge pads 106a, 116a, for example forming a straight vertical line up the modules 160 in device 170. Electrical traces 174 may also be formed extending between the columns as shown. Thus, the electrical traces 174 connect the bond pads 106, 116, 108 and/or 118 to the solder bumps 172. The particular pattern of solder bumps 172 and electrical traces 174 in FIG. 12 is a way of example only, and may be any of a wide variety of other patterns in further embodiments. As used herein, a pattern of electrical traces may be any pattern of electrical traces 174 extending between two or vertical edge pads (106a, 116a, 108a, 118a), or between such pads and a solder bump 172.

The pattern of electrical traces 174 may be formed by a variety of different technologies. However, in one embodiment, a conductive seed layer may be applied to vertical sidewall 170a. The seed layer may be a thin film produced in a PVD (physical vapor deposition) process, and may for example be formed of titanium, nickel, copper or stainless steel sputtered onto the sidewall 170a. The seed layer may be formed of other electrical conductors and may be applied by other thin film deposition techniques in further embodiments. The seed layer may be 2-5 μm, but may be thicker or thinner than that in further embodiments. Annealing heating may optionally be performed to purge a metal grain condition in the seed layer.

Next, the seed layer may be processed to remove portions of the layer and leave behind the desired pattern of electrical traces 174. In one example, a layer of photoresist may be spray coated over the seed layer. A pattern may be formed in the photoresist layer by the lithography (either a positive or negative image of the eventual electrical trace pattern), and the lithography pattern may be developed to expose the seed layer in the desired pattern through the photoresist. The exposed seed layer may be electroplated, and then the residual photoresist may be removed. A polyimide protective insulating layer may be coated and cured over the pattern of traces 174. The pattern of electrical traces 174 may be formed by other photolithographic and non-photolithographic processes in further embodiments. Such additional processes include screen printing of the conductive traces in the shape of the electrical traces 174, and additive manufacturing to print the electrical traces 174.

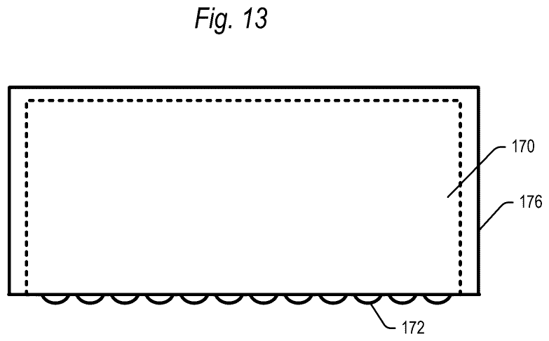

Optionally, in a final step, the CBA semiconductor device may be encased in a molding compound 176 as shown in FIG. 13, covering all sides but leaving the side including the solder bumps exposed. The molding compound may be applied in known processes such as by transfer molding, injection molding or by FFT (Flow Free Thin) compression molding.

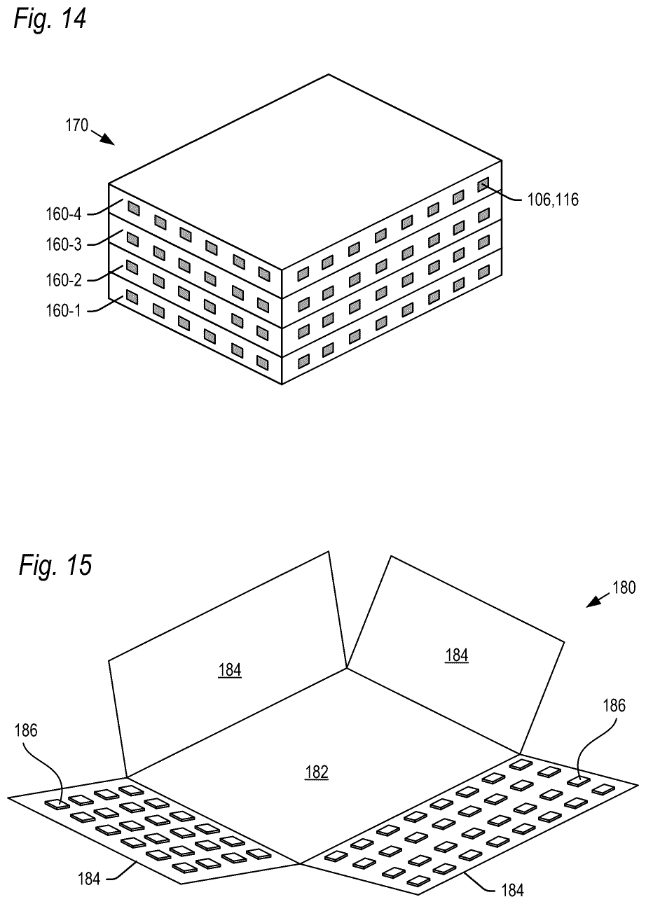

FIGS. 14-16 relate to a further embodiment of the present technology, where a CBA semiconductor device 170, formed of one or more CBA memory modules 160, is encased in a flexible substrate 180. FIG. 14 shows a CBA semiconductor device 170 as described above, but in this embodiment the solder bumps 172 (FIG. 11) are omitted. As above, the CBA semiconductor device 170 may have various numbers of CBA memory modules 160. In this embodiment, each of the CBA memory modules may have edge pads 106, 116 and/or edge pads 108, 118 on one or more vertical sidewalls of the CBA semiconductor device 170, including up to on all four vertical sidewalls.

FIG. 15 is a perspective view of a flexible substrate 180 including a base 182 and sides 184 which fold upward relative to the base 182. Substrate 180 including base 182 and sides 184 may be formed of a rigid material, except where the sides meet the base. At these sections, the substrate 180 may be flexible. In such embodiments, the base 182 and sides 184 may be formed of standard substrate materials including one or more electrically conductive layers separated by dielectric layers. The conductive layers may be formed of copper etched into conductance patterns. The dielectric layers may be polyimide laminates, epoxy resins including FR4 and FR5, bismaleimide triazine (BT), and the like. In further embodiments, the substrate 180 may be a flexible printed circuit (also referred to as a flex circuit) including conductive layers, such as copper, etched into conductance patterns, and dielectric layers separating the conductive layers. The dielectric layers in this embodiment may be formed a flexible polymer such as polyimide, PEEK, PET, polyester or other thin films

The substrate 180 is a signal-carrier medium provided for transferring electrical signals between CBA semiconductor device 170 and a host device such as a printed circuit board (not shown) on which the substrate 180 is mounted. In particular, one or more of the folding sides 184 may be formed with electrical connectors such as contact pads 186. FIG. 15 shows contact pads 186 formed on two of the folding sides 184. However, in embodiments, one, two, three or all four sides 184 may include contact pads 186. In embodiments, the number of sides 184 including contact pads 186 may match the number of sidewalls in CBA semiconductor device 170 that include bond pads 106, 116 and/or 108, 118. Where a side 184 includes contact pads 186, the number and pattern of contact pads 26 match the number and pattern of bond pads on the CBA semiconductor device 170.

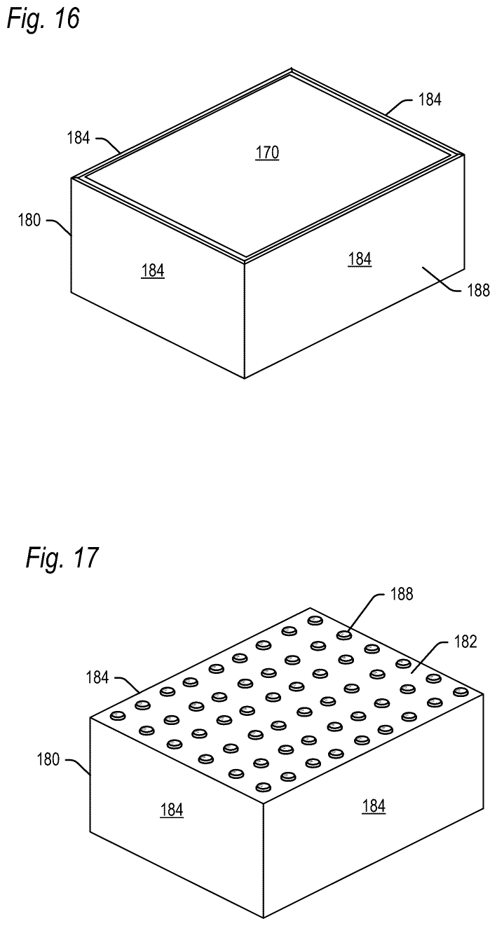

In assembly, a completed CBA semiconductor device 170 as shown in FIG. 14 may be placed on the substrate 180 so that a bottom of the device 170 rests on base 182 of substrate 180. Thereafter, the sides 184 may be folded upward so that the contact pads 186 lie in physical contact respective ones of bond pads 106, 116 and/or 108, 118. Thereafter, the side 184 may be adhered to the side walls of the CBA semiconductor device 170. This may be done by reflowing the contact pads 186 to adhere to their respective bond pads and/or using an electrically insulative adhesive to adhere the sides 184 to the sidewalls of the CBA semiconductor device 170. FIG. 16 is a perspective view of the substrate 180 with the sides 184 folded upward and positioned against the side walls of the CBA semiconductor device 170.

FIG. 17 is a bottom perspective view of the substrate 180 further showing solder bumps 188 on a side of the base 182 opposite that supporting the CBA semiconductor device 170. The solder bumps 188 may alternatively or additionally be formed on one or more of the sides 184, facing exteriorly of the CBA semiconductor device 170 (that is, on a surface of the sides 184 opposite that including the contact pads 186). The conductance pattern(s) of the one or more conductive layers within substrate 180 carry signals, power and ground between the solder bumps 188 and the bond pads of the CBA semiconductor device 170. The solder bumps 188 may in turn be mounted to a host device such as a printed circuit board as mentioned above to allow communication between the host device and the CBA semiconductor device 170.

In addition to electrically coupling the CBA semiconductor device 170 to a host device, the substrate 180 provides a protective enclosure to the CBA semiconductor device 170. However, in further embodiments, the substrate 180 and CBA semiconductor device 170 may be encased in molding compound, leaving the surface including solder bumps 188 exposed, as described above.

In summary, an example of the present technology relates to a CMOS bonded array (CBA) memory module, comprising: a first semiconductor die comprising at least a first group of bond pads, the first group of bond pads having surfaces exposed at an edge of the first semiconductor die; a second semiconductor die comprising at least a second group of bond pads, the second group of bond pads having surfaces exposed at an edge of the second semiconductor die; wherein the first semiconductor die is bonded to the second semiconductor die such that the at least first group of bond pads of the first semiconductor die are electrically and physically coupled to the at least second group of bond pads of the second semiconductor die, the first and second groups of bond pads having joined exposed surfaces at a face of the joined first and second semiconductor dies.

In another example, the present technology relates to a CMOS bonded array (CBA) semiconductor device comprising: a plurality of stacked CBA memory modules, the plurality of stacked CBA memory modules defining a planar sidewall, each of the CBA memory modules comprising: a first semiconductor die comprising at least a first group of bond pads, the first group of bond pads having surfaces exposed the planar sidewall; a second semiconductor die comprising at least a second group of bond pads, the second group of bond pads having surfaces exposed at the planar sidewall; and electrical traces formed on the sidewall and electrically coupling bond pads from the first and second groups to each other.

In another example, the present technology relates to a CMOS bonded array (CBA) semiconductor device comprising: a plurality of stacked CBA memory modules, the plurality of stacked CBA memory modules defining a planar sidewall, each of the CBA memory modules comprising: a first semiconductor die comprising at least a first group of bond pads, the first group of bond pads having surfaces exposed the planar sidewall; a second semiconductor die comprising at least a second group of bond pads, the second group of bond pads having surfaces exposed at the planar sidewall; and a substrate on which the plurality of stacked CBA memory modules are supported, the substrate comprising at least one foldable side, the foldable side folded upward into contact with the sidewall to carry electrical signals to and from the first and second groups of bond pads.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A CMOS bonded array (CBA) memory module, comprising:
a first semiconductor die comprising at least a first group of bond pads, the first group of bond pads having surfaces exposed at an edge of the first semiconductor die;
a second semiconductor die comprising at least a second group of bond pads, the second group of bond pads having surfaces exposed at an edge of the second semiconductor die;
wherein the first semiconductor die is bonded to the second semiconductor die such that the at least first group of bond pads of the first semiconductor die are electrically and physically coupled to the at least second group of bond pads of the second semiconductor die, the first and second groups of bond pads having joined exposed surfaces at a face of the joined first and second semiconductor dies.

2. The CBA memory module of claim 1, wherein the first and second coupled semiconductor dies together are configured as an integrated flash memory.

3. The CBA memory module of claim 1, wherein the first semiconductor die comprises a plurality of memory cells.

4. The CBA memory module of claim 3, wherein the second semiconductor die comprises a control circuit for controlling access to the plurality of memory cells.

5. The CBA memory module of claim 4, wherein the control circuit comprises a complementary metal-oxide-semiconductor integrated circuit.

6. The CBA memory module of claim 1, wherein the first group of bond pads comprise input/output (I/O) signal pads.

7. The CBA memory module of claim 1, wherein the first group of bond pads comprise test pads for testing operational quality of the first semiconductor die.

8. The CBA memory module of claim 1, wherein the first group of bond pads comprise input/output (I/O) signal pads and test pads for testing operational quality of the first semiconductor die.

9. The CBA memory module of claim 1, further comprising a third group of bond pads on the first semiconductor die spaced inward from edges of the first semiconductor die, the third group of bond pads configured for testing operational quality of the first semiconductor die.

10. The CBA memory module of claim 1, further comprising a fourth group of bond pads on a first major surface of the first semiconductor die, the fourth group of bond pads electrically coupled to a fifth group of bond pads on a second major surface of the first semiconductor die opposite the first major surface.

11. The CBA memory module of claim 1, wherein the edge of the first semiconductor die comprises a first edge of the first semiconductor die, and wherein the first group of bond pads further have surfaces exposed at at least a second edge of the first semiconductor die.

12. A CMOS bonded array (CBA) semiconductor device comprising:
a plurality of stacked CBA memory modules, the plurality of stacked CBA memory modules defining a planar sidewall, each of the CBA memory modules comprising:
a first semiconductor die comprising at least a first group of bond pads, the first group of bond pads having surfaces exposed the planar sidewall;
a second semiconductor die comprising at least a second group of bond pads, the second group of bond pads having surfaces exposed at the planar sidewall; and
electrical traces formed on the sidewall and electrically coupling bond pads from the first and second groups to each other.

13. The CBA semiconductor device of claim 12, wherein bond pads from the first and second groups are electrically and physically coupled to each other.

14. The CBA semiconductor device of claim 12, further comprising a plurality of solder bumps formed on a surface of the CBA semiconductor device, the solder bumps configured to transfer signals between the first and second groups of bond pads and a host device on which the CBA semiconductor device is mounted.

15. The CBA semiconductor device of claim 14, wherein the electrical traces are further formed on the surface of the CBA semiconductor device comprising the solder bumps and are electrically and physically coupled to the solder bumps.

16. The CBA semiconductor device of claim 12, wherein the sidewall comprises a first sidewall, the first and second groups of bond pads further comprising edges exposed at at least a second sidewall of the CBA semiconductor device.

17. A CMOS bonded array (CBA) semiconductor device comprising:
a plurality of stacked CBA memory modules, the plurality of stacked CBA memory modules defining a planar sidewall, each of the CBA memory modules comprising:
a first semiconductor die comprising at least a first group of bond pads, the first group of bond pads having surfaces exposed the planar sidewall;
a second semiconductor die comprising at least a second group of bond pads, the second group of bond pads having surfaces exposed at the planar sidewall; and
a substrate on which the plurality of stacked CBA memory modules are supported, the substrate comprising at least one foldable side, the foldable side folded upward into contact with the sidewall to carry electrical signals to and from the first and second groups of bond pads.

18. The CBA semiconductor device of claim 17, wherein the substrate comprises a base supporting the plurality of CBA memory modules and four foldable sides extending upward to enclose the plurality of CBA memory modules.

19. The CBA semiconductor device of claim 17, further comprising a pattern of contact pads on the at least one foldable side, the contact pads in the pattern coupling with the bond pads from the first and second group exposed at the sidewall.

20. The CBA semiconductor device of claim 19, wherein the substrate further comprises a pattern of solder bumps on a surface of the substrate facing exteriorly of the plurality of CBA memory modules, the solder bumps electrically coupled to the contact pads through the substrate.
